(19) United States
(12) Patent Application Publication
(10) Pub. No.: US 2013/0120829 A1
(43) Pub. Date: May 16, 2013

(54) HIGH SPEED SOLID STATE OPTICAL SWITCHING SYSTEM USING BICONTINUOUS STRUCTURES

(71) Applicant: Technology Innovations, LLC, Pittsford, NY (US)

(72) Inventor: Robert William Corkery, Stockholm (SE)

(73) Assignee: Technology Innovations, LLC, Pittsford, NY (US)

(21) Appl. No.: 13/550,923

(22) Filed: Jul. 17, 2012

Related U.S. Application Data
(60) Provisional application No. 61/508,660, filed on Jul. 17, 2011.
(60) Provisional application No. 61/547,184, filed on Oct. 14, 2011.
(60) Provisional application No. 61/671,878, filed on Jul. 16, 2012.

(51) Int. Cl. G02F 1/29; H05K 1/02

(52) U.S. Cl. CPC G02F 1/29; H05K 1/0284; H05K 1/0212
USPC 359/320; 174/250; 174/252

(57) ABSTRACT

A bicontinuous optical switching structure includes a predetermined number of tunnels coated with a reflective material or a very smooth. The tunnels provide pathways from one side of bicontinuous optical switching structure to another. Each tunnel represents an entry point having a multitude of entry angles. Since the angle of entry dictates the exit point, a single tunnel can represent multiple entry/exit point pairs. A three-dimensional circuit may include a hyperbolic bicontinuous structure forming a substrate; circuits formed on a first surface of the hyperbolic bicontinuous structure; and electrically conductive traces formed between the circuits. The electrically conductive traces are formed two-dimensionally on the first surface of the hyperbolic bicontinuous structure. The electrically conductive traces are effectively three-dimensional traces between the circuits.

### PRIORITY INFORMATION

This application claims priority, under 35 U.S.C. §119(e), from U.S. Provisional Patent Application Ser. No. 61/508,660, filed on Jul. 17, 2011. The entire content of U.S. Provisional Patent Application Ser. No. 61/508,660, filed on Jul. 17, 2011, is hereby incorporated by reference.

This application further claims priority, under 35 U.S.C. §119(e), from U.S. Provisional Patent Application Ser. No. 61/547,184, filed on Oct. 14, 2011. The entire content of U.S. Provisional Patent Application Ser. No. 61/547,184, filed on Oct. 14, 2011, is hereby incorporated by reference.

This application further claims priority, under 35 U.S.C. §119(e), from U.S. Provisional Patent Application Ser. No. 61/671,878, filed on Jul. 16, 2012. The entire content of U.S. Provisional Patent Application Ser. No. 61/671,878, filed on Jul. 16, 2012, is hereby incorporated by reference.

### BACKGROUND

Light modulating mirror devices have been developed in which a mirror or reflector is can be positioned at various locations to either direct the impinging light to one location or to direct the impinging light to another location.

When a voltage is applied to one region housing the mirror, the mirror is moved so that the impinging light is directed to a first location. When the voltage is removed or applied to another region housing the mirror, the mirror is moved so that the impinging light is directed to a second location.

Such a device can be implemented in a variety of optical applications. For example, U.S. Pat. No. 5,061,049, issued on Oct. 29, 1991, entitled “Spatial Light Modulator and Method,” describes an spatial light modulator with a movable mirror.

Spatial light modulators are transducers that modulate incident light in a spatial pattern corresponding to an electrical or optical input. The incident light may be modulated in its phase, intensity, polarization, or direction, and the light modulation may achieved by a variety of materials exhibiting various electrooptic or magnetoopotic effects and by materials that modulate light by surface deformation.

An example of a prior art single pixel electrostatic (rigid) movable mirror device is illustrated by FIG. 1. The pixel, generally denoted 20, is basically a plate (flap) covering a shallow well and includes silicon substrate 22, insulating spacer 24, metal hinge layer 26, metal plate layer 28, plate 30 formed in layers 26-28, and plasma etch access holes 32 in plate 30. The portions 34 & 36 of hinge layer 26 that are not covered by plate layer 28 form torsion hinges (torsion rods) attaching beam 30 to the portion of layers 26-28 supported by spacer 24. Electrodes 40, 42, 46, and 41 run between spacer 24 and substrate 22 and are isolated from substrate 22 by silicon dioxide layer 44.

The design of FIG. 1 allows that the plate metal be as thick as desired and the hinge metal be as thin as desired without the problems of step coverage of the hinge metal over the plate metal and that the spacer surface under the beam metal is not exposed to processing side effects which would arise if the hinge were formed as a rectangular piece on the spacer prior to deposition of the plate metal.

Pixel 20 is operated by applying a voltage between metal layers 26-28 and electrodes 42 or 46 on substrate 22: beam 30 and the electrodes form the two plates of an air gap capacitor and the opposite charges induced on the two plates by the applied voltage exert electrostatic force attracting beam 30 to substrate 22, whereas electrodes 40 and 41 are held at the same voltage as beam 30. This attractive force causes beam 30 to twist at hinges 34 and 36 and be deflected towards substrate 22.

FIG. 1 also indicates the reflection of light from deflected beam 30 as may occur during operation of a deformable mirror device. The deflection of beam 30 can be a highly non-linear function of the applied voltage because the restoring force generated by the twisting of hinge 34 is approximately a linear function of the deflection but the electrostatic force of attraction increases as a function of the reciprocal of the distance between the closest corner of beam 30 and substrate 22.

Conventional optical switches provide single path switching for single lasers or single beam of light.

Therefore, it is desirable to provide an optical switching system that is capable of multiple sub-pathway switching without negatively impacting the switching speed. Furthermore, it is desirable to provide an optical switching system that is capable of handling multiple lasers or beams of light without negatively impacting the switching speed.

It is noted that higher integration of semiconductor devices is desired for superior performance and/or reducing the price of electronic devices.

Accordingly, three-dimensional semiconductor devices having a stacked structure have been fabricated, wherein the stacked structure includes a first layer, a second layer, a third layer, and a fourth layer sequentially stacked on a substrate. An example of such a structure is illustrated in FIG. 29.

In FIG. 29, a first layer 2110 is formed. Upon the first layer 2110, circuits 2205 and 2210 are formed. In this example, circuits 2205 and 2210 are formed on the same plane of layer 2110. Wiring or conductive traces 2310 are formed between circuits 2205 and 2210.

Upon first layer 2110, a second layer 2120 is formed. It is noted that an air gap may be formed between first layer 2110 and second layer 2120.

Upon the second layer 2120, circuits 2215 and 2220 are formed. In this example, circuits 2215 and 2220 are formed on the same plane of layer 2120. Wiring or conductive traces 2325 are formed between circuits 2215 and 2220.

Upon second layer 2120, a third layer 2130 is formed. It is noted that an air gap may be formed between second layer 2120 and third layer 2135.

Upon the third layer 2130, circuits 2225, 2230, and 2235 are formed. In this example, circuits 2225, 2230, and 2235 are formed on the same plane of layer 2130. Wiring or conductive traces 2340 and 2345 are formed between circuits 2225, 2230, and 2235.

Upon third layer 2130, a fourth layer 2140 is formed. It is noted that an air gap may be formed between third layer 2130 and fourth layer 2140.

Upon the fourth layer 2140, circuits 2240, 2245, and 2250 are formed. In this example, circuits 2240, 2245, and 2250 are formed on the same plane of layer 2140. Wiring or conductive traces 2360 and 2365 are formed between circuits 2240, 2245, and 2250.

To provide electrical connectivity between layers, wiring or conductive traces 2425 and 2475 are vertically formed between layers 2110, 2120, 2130, and 2140. Wiring or conductive traces 2305, 2315, 2320, 2330, 2335, 2350, 2355, and 2370 are formed to provide electrical connectivity between the various circuits and vertical conductive traces 2425 and 2475.

It is noted that wiring or conductive traces 2425 and 2475 may be integral with wiring or conductive traces 2305, 2315, 2320, 2330, 2335, 2350, 2355, and 2370.

Another example of a stacked structure is disclosed in Published US Patent Application Number 2012/0171861. The entire content of Published US Patent Application Number 2012/0171861 is hereby incorporated by reference.

In these conventional devices, the conductive traces that provide connectivity between levels or layers include 90 degree bends. These 90 degree bends produce heat and consume power.

Thus, it is desirable to provide a three-dimensional circuit architecture with traces that have no 90 degree or tight bends.

Moreover, it is desirable to provide a three-dimensional circuit architecture that realizes less heat, less power consumption, optimally shorter paths, and higher connectivity options.

### BRIEF DESCRIPTION OF THE DRAWINGS

The drawings are only for purposes of illustrating embodiments and are not to be construed as limiting, wherein:

FIG. 1 illustrates single pixel electrostatic (rigid) movable mirror device;

FIG. 2 illustrates a block diagram of an optical switching system using a bicontinuous structure;

FIG. 3 illustrates an example of a bicontinuous optical switching structure directing a green laser in a predetermined direction;

FIG. 4 illustrates another example of a bicontinuous optical switching structure directing the green laser in a predetermined direction;

FIG. 5 illustrates a third example of a bicontinuous optical switching structure directing the green laser in a predetermined direction;

FIG. 6 illustrates a fourth example of a bicontinuous optical switching structure directing the green laser in a predetermined direction;

FIG. 7 illustrates an example of a bicontinuous optical switching structure directing multiple color lasers in different predetermined directions;

FIG. 8 illustrates another example of a bicontinuous optical switching structure directing multiple color lasers in different predetermined directions;

FIG. 9 illustrates a third example of a bicontinuous optical switching structure directing multiple color lasers in different predetermined directions;

FIG. 10 illustrates a block diagram of an optical switching system using a bicontinuous structure and embedded electronic devices in or on the hyperbolic internal structures;

FIG. 11 shows an entry angle or trajectory of laser beams entering the opening of a tunnel of a bicontinuous structure from a perspective of looking into the entrance of the tunnel;

FIG. 12 shows an entry angle or trajectory of laser beams entering the opening of a tunnel of a bicontinuous structure from a perspective of looking across the face of the entrance of the tunnel;

FIG. 13 shows an example of a device having multiple hyperbolic bicontinuous structures forming mutually interpenetrating labyrinths;

FIG. 14 shows another example of a device having multiple hyperbolic bicontinuous structures forming mutually interpenetrating labyrinths;

FIG. 15 shows a third example of a device having multiple hyperbolic bicontinuous structures forming mutually interpenetrating labyrinths;

FIG. 16 shows an annotated example of a device having multiple hyperbolic bicontinuous structures forming mutually interpenetrating labyrinths;

FIG. 17 illustrates a D-surface cubosome closed by a cube;

FIG. 18 illustrates an annotated example of a device having multiple hyperbolic bicontinuous structures forming mutually interpenetrating labyrinths;

FIGS. 19-22 illustrate circuits having a fully three-dimensional structure, while only requiring a two-dimensional wiring architecture;

FIG. 23 shows an example of quantum dots or photonic dots;

FIG. 24 illustrates an example of a hyperbolic bicontinuous structure;

FIG. 25 illustrates an example of a “Batwing’ minimal surface structure;

FIG. 26 illustrates an example of a CLP minimal surface structure;

FIG. 27 illustrates another example of a CLP minimal surface structure;

FIG. 28 illustrates an example of a catenoid minimal surface structure;

FIG. 29 illustrates a conventional three-dimensional circuit;

FIG. 30 illustrates an example of locating circuitry on a hyperbolic bicontinuous structure; and

FIG. 31 illustrates an example of locating circuitry on one side of a hyperbolic bicontinuous structure and having a coolant flow along the other side of the hyperbolic bicontinuous structure.

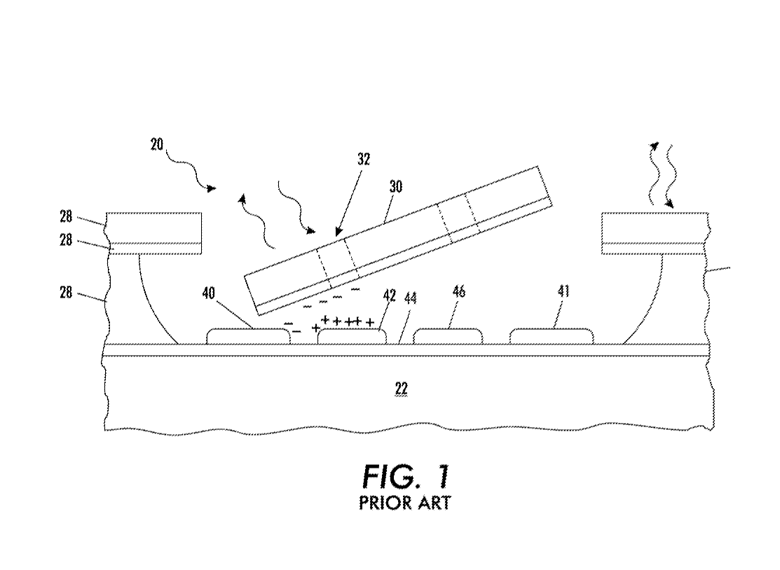

### DETAILED DESCRIPTION

For a general understanding, reference is made to the drawings. In the drawings, like reference have been used throughout to designate identical or equivalent elements. It is also noted that the various drawings may not have been drawn to scale and that certain regions may have been purposely drawn disproportionately so that the features and concepts could be properly illustrated.

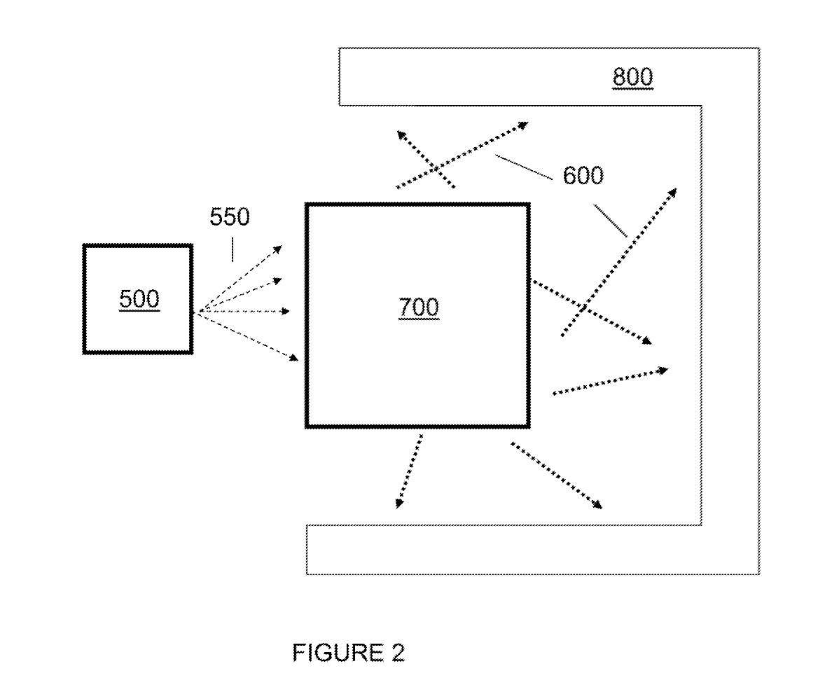

As discussed above, it is desirable to provide an optical switching system that is capable of multiple sub-pathway switching without negatively impacting the switching speed. Furthermore, it is desirable to provide an optical switching system that is capable of handling multiple lasers or beams of light without negatively impacting the switching speed. An example of such an optical switching system is illustrated in FIG. 2.

As illustrated in FIG. 2, a laser source 500 provides a single laser which can be deflected (directed) in multiple directions, as illustrated by the dashed line arrows 550. The laser 550 is inputted into a bicontinuous optical switching structure 700, at a predetermined point of entry or angle. The laser travels through the bicontinuous optical switching structure 700. The laser 600 exits an exit point depending upon the predetermined point of entry or angle. The exiting laser can be collected by a device 800 for sensing, further transmission, processing, and/or modulation, etc.

The bicontinuous optical switching structure 700 is an optical switching system that includes a large number of switching channels. The switching channels are all optical and do not impede signal transmission.

As noted above, the optical switch comprises complex bicontinuous structures formed of bicontinuous surfaces. Examples of bicontinuous surfaces are bicontinuous minimal surfaces, such as the gyroid (the D and the P surfaces). Such bicontinuous surfaces are well known to those skilled in the art.

The bicontinuous structures are characterized by mutually interpenetrating labyrinths and contain a hyperbolically curved interface.

It is noted that the term hyperbolic refers only to the curvature at a point. The average curvature of the surface extended to infinity could indicate that the overall average point is hyperbolic.

It is noted that there may be some flat points in the structures, but on average each point has a hyperbolic curvature; i.e., the two principle curvatures at a point are of opposite signs, and thus, the product thereof or Gaussian curvature is opposite.

The bicontinuous optical switching structure 700 includes a predetermined number of tunnels which can be coated with a reflective material or grinded to a very smooth surface to provide the desired reflective properties.

The tunnels provide pathways from one side of bicontinuous optical switching structure 700 to another. It is noted that the tunnels may be continuous from one side to the other but may intersect other tunnels to provide a greater number of the multiple exit points in a three-dimensional space.

Each tunnel represents an entry point having a plurality of potential optical entry point. Each potential optical entry point may be a physical location on the bicontinuous structure.

The distribution of curvature in the structure can vary. In the most homogeneous case, the surface is called the gyroid. Other known surfaces have more curvature variation. The mean curvature at each point can be constant or close to constant. These are the set of mean curvature surfaces.

It is further noted that, with respect to a bicontinuous surface, a light beam enters one set of branched tunnels at a point and exits from the other set of branched tunnels. Thus, there are in fact two sets of possible inputs and outputs, unless punctures are placed in the surface to allow photons to travel to the other side. A single puncture means the surface no longer defines a set of separate tunnel labyrinths since the tunnels are now connected. Thus, the system is no longer bicontinuous.

In addition to bicontinuous surfaces, the optical switch may be formed of tricontinuous surfaces and multi-continuous surfaces in which multiple sets of tunnel systems are separated by a single surface. In these cases, there will be multiple sets of unconnected branching tunnel networks within the structure. These can also be of high and low symmetry, high and low degree of periodic order and with and without punctures.

It is noted that the optical switch may be formed of nested sets of bicontinuous surfaces.

In addition, it is noted that the optical switch may be formed of bicontinuous or multi-continuous surfaces, and variations thereof, in combination with any other surface either on the inside or outside of the structure. For example, a bicontinuous surface may be utilized with a sphere in a tunnel.

In addition, each potential optical entry point for a tunnel may correspond to a different angle of incidence at a single physical location on the bicontinuous structure.

Furthermore, each potential optical entry point may be a physical location on the bicontinuous structure and each potential optical entry point may correspond to a different angle of incidence at the physical location on the bicontinuous structure such that the multiple potential optical entry points form a three-dimensional set of potential optical entry points for each tunnel.

Depending upon the entry point and the entry angle, the entering light beam will exit at a precise point from the bicontinuous optical switching structure 700. In other words, the angle of entry and the entry point (assuming multiple entry points) dictates the position and angle of the exiting light beam or the exit point.

It is further noted that each entry point may have several output points if, for example, the photon splits in two.

Based upon this dependency, the entry points and corresponding exit points of a particular bicontinuous optical switching structure can be precisely mapped.

Moreover, since the physical location of incidence and the angle of incidence dictate the exit point, a single tunnel can represent multiple entry/exit point pairs. Thus, a single tunnel can provide a multitude of sub-pathways in the tunnel for multiple beams without the beams impeding each other.

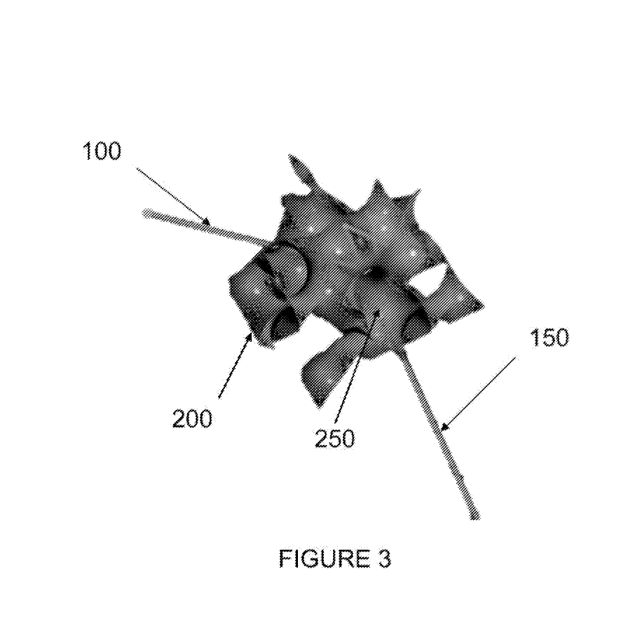

Examples of a single laser beam entering a tunnel at different angles of entry are illustrated in FIGS. 3 through 6.

As illustrated in FIG. 3, a laser 100 enters a tunnel of the bicontinuous optical switching structure 200 at a certain angle. Based upon this angle of entry and the corresponding tunnel, the laser 150 exits from the bicontinuous optical switching structure 200 at a certain exit point 250.

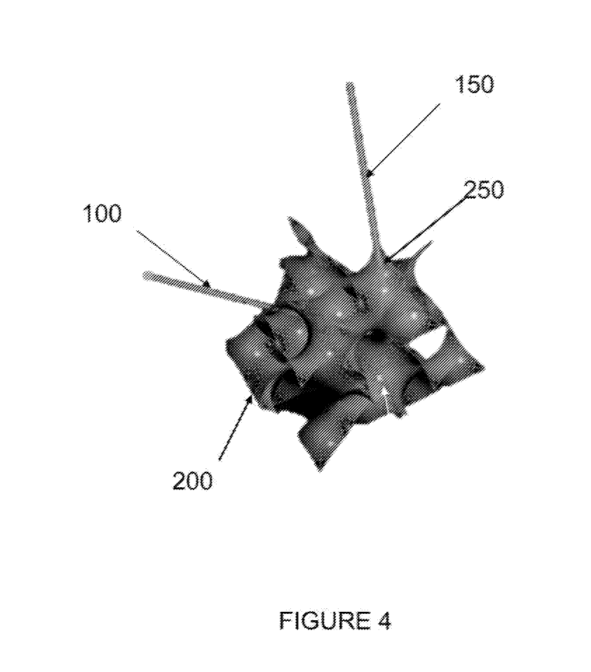

As illustrated in FIG. 4, a laser 100 enters the same tunnel of the bicontinuous optical switching structure 200 but a different angle. Based upon this different angle of entry, the laser 150 exits from the bicontinuous optical switching structure 200 at a different exit point 250.

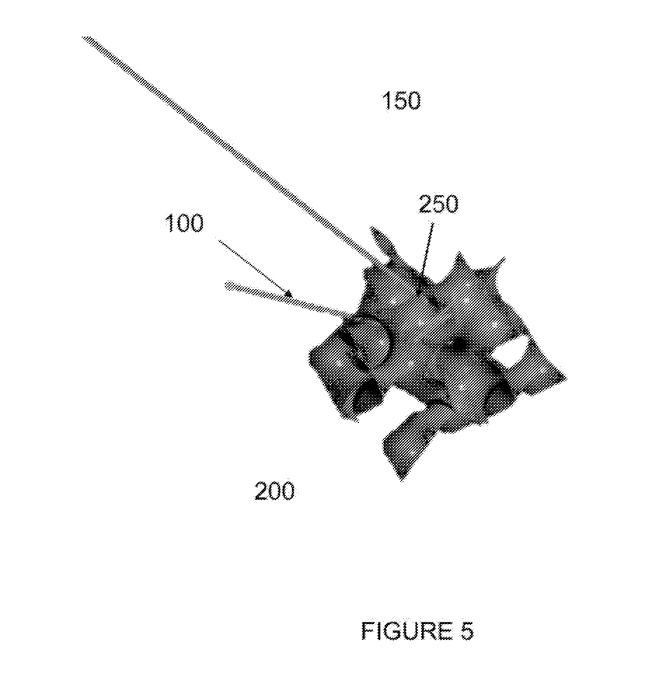

As illustrated in FIG. 5, a laser 100 enters the same tunnel of the bicontinuous optical switching structure 200 but an angle different from the angles of FIGS. 3 and 4. Based upon this different angle of entry, the laser 150 exits from the bicontinuous optical switching structure 200 at still another different exit point 250.

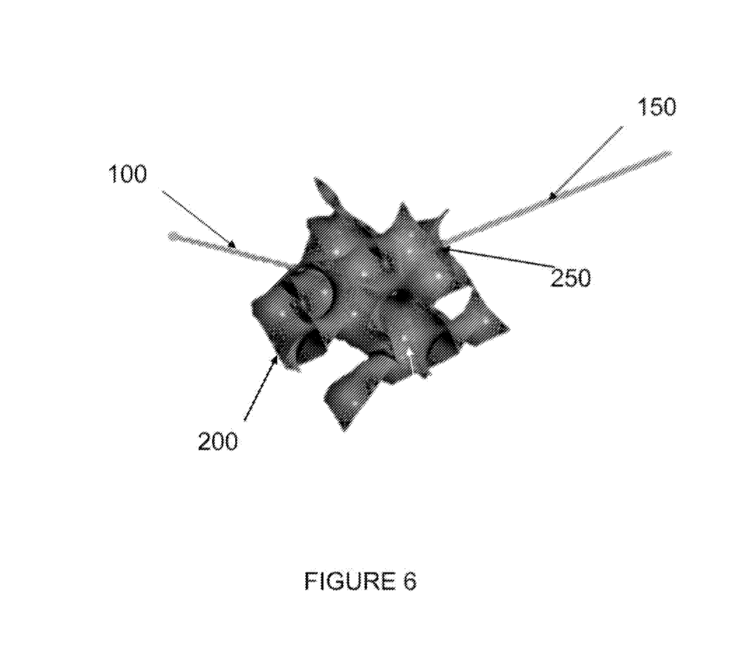

As illustrated in FIG. 6, a laser 100 enters the same tunnel of the bicontinuous optical switching structure 200 but an angle different from the angles of FIGS. 3, 4, and 5. Based upon this different angle of entry, the laser 150 exits from the bicontinuous optical switching structure 200 at still another different exit point 250.

As previously stated, by directing the laser at different angles of entry, a mapping of the exit points to entry points can be generated so as to provide an effective switching device.

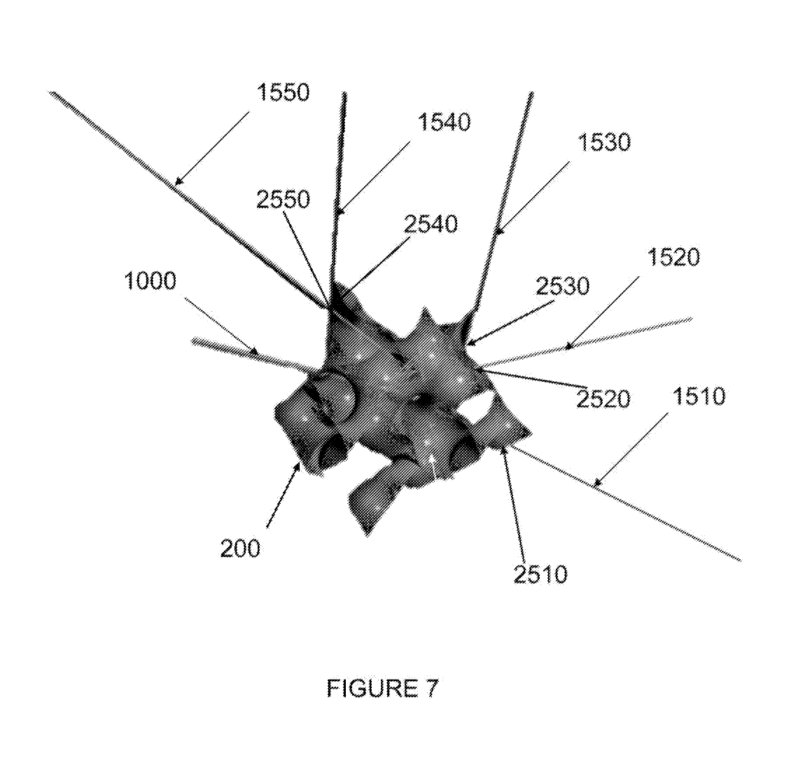

Examples of multiple laser beams entering a tunnel at different angles of entry are illustrated in FIGS. 7 through 9.

As illustrated in FIG. 7, multiple laser beams 1000 enter the same tunnel of the bicontinuous optical switching structure 200, but each at a different angle. Based upon these different angles of entry, the lasers (1510, 1520, 1530, 1540, and 1550) exit from the bicontinuous optical switching structure 200 at different points (2510, 2520, 2530, 2540, and 2550), respectively.

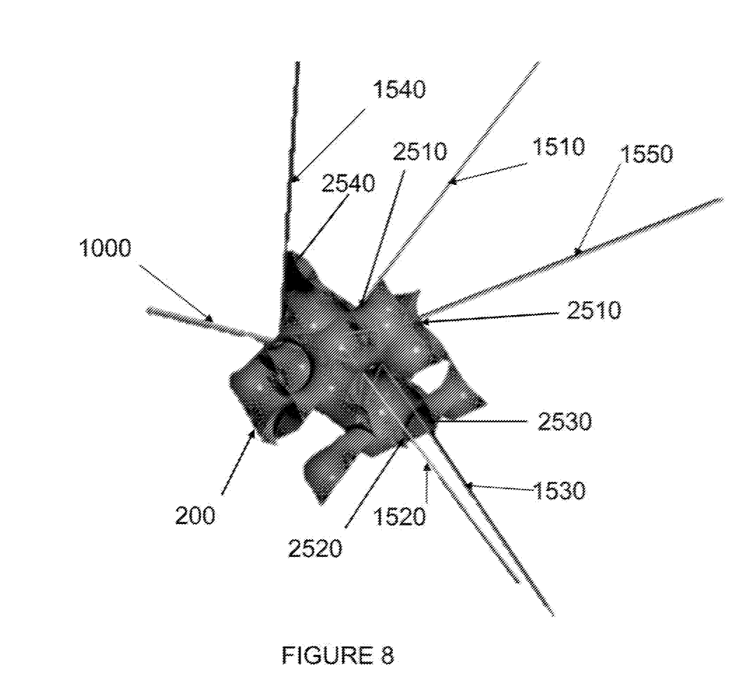

As illustrated in FIG. 8, multiple laser beams 1000 enter the same tunnel of the bicontinuous optical switching structure 200, but each at a different angle and different from the angles illustrated in FIG. 7. Based upon these different angles of entry, the lasers (1510, 1520, 1530, 1540, and 1550) exit from the bicontinuous optical switching structure 200 at different points (2510, 2520, 2530, 2540, and 2550), respectively.

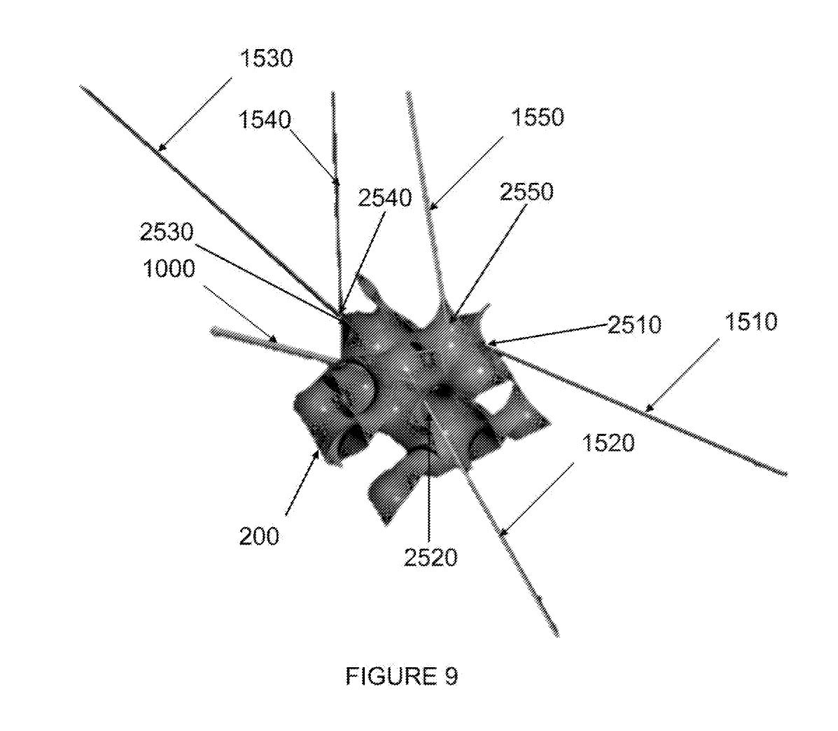

As illustrated in FIG. 9, multiple laser beams 1000 enter the same tunnel of the bicontinuous optical switching structure 200, but each at a different angle and different from the angles illustrated in FIGS. 7 and 8. Based upon these different angles of entry, the lasers (1510, 1520, 1530, 1540, and 1550) exit from the bicontinuous optical switching structure 200 at different points (2510, 2520, 2530, 2540, and 2550), respectively.

It is noted that although the Figures show the laser entering one side of the bicontinuous optical switching structure 200, the laser can enter any tunnel around the bicontinuous optical switching structure 200. In all the various possibilities of entry points, the exit point is dictated by the entry point and angle of entry and can be easily measured and mapped.

The bicontinuous optical switching structure allows each tunnel to have a large number of sub-pathways which do not impede the speed of connectivity.

It is noted that the entry point and angle of entry can be controlled by a MEMS mirror system or an optical deflection device. Moreover, the entry point and angle of entry can be set by the positioning of the laser source or fiber optic or light channel carrying the light beam.

It is further noted that the angular pathways within the tunnel(s) create a form of switching identification (entry/exit point pair) that is incremental to the information within the beam.

Moreover, a second bicontinuous optical switching structure can be added (stacked) to the first bicontinuous optical switching structure, by mating the tunnel entrance (exit) of one bicontinuous optical switching structure to the tunnel exit (entrance) of the other bicontinuous optical switching structure, to increase selectivity.

Control of the beams and their respective angle of entry can be realized by deflecting the laser beam from its source to the entrance to the tunnel. There are many forms of modulation of lasers, such as a MEMS mirror system wherein the mirrors can be manipulated to be ON/OFF or have a particular angle of deflection.

The entry point of the laser beam can be mapped to its measured exit point such that the bicontinuous optical switching structure can be used to route the laser beam to another switch, to a cable, a fiber optic, to an optical storage device, a signal modulator, and/or other optical components.

In addition to deflection, modulation of the beam and/or color can be used to modify the incoming beam for mapping to an output beam. Moreover, using interference patterns and/or other forms of adaptation to the beams to cancel out parts of the beam can be utilized in providing identification for mapping purposes.

As FIGS. 3-9 illustrate, the beam selectivity is largest when the beam hits certain critical points on the surface at certain angles such that a small shift in the angle results in a large change in output path. A multitude of these critical points exists on the surface of the hyperbolic bicontinuous structures, depending on the intrinsic surface curvature of the hyperbolic bicontinuous structures and orientation of the hyperbolic bicontinuous structures to the beam. If the beam hits several of these critical points consecutively, the number of possible outputs exponentially rises.

Based upon the characteristics of these critical points, a beam can be aimed close to, but not quite exactly on the critical point, to effect very quick switching, thereby increasing the range of possible paths through the hyperbolic bicontinuous structures. This allows the optical switch to effectively operate at the edge of chaos.

Regarding the entry angles of the light entering the optical switch, there are basically three situations involving directing the initial light source and keeping the mirror fixed: (1) when the light source is outside the bounding volume of the surface; (2) when the light source comes from within the free space of the bounded surface and (3) when the light source is embedded in the surface.

For these situations, mirrors (planar or curved) may be used to change the incident angle relative to the bicontinuous mirror. This would only require extremely small motions to change the incoming direction of the light (flexible or not). Moreover, lenses, prisms, gratings, beam splitters, waveguides, tunable non-linear optical devices, or responsive optical elements that change shape/orientation, etc. may be used to achieve different incident angles.

For example, a non-linear waveguide that uses light from a different signal to change its optical properties refractive index can be used. In this example, a pulsed control laser incident on a non-linear crystal, wherein the optical properties vary with the frequency of the pulse. In addition, a second laser containing information to be switched between two channels by changing its angle of incidence relative to the bicontinuous mirror is added. If the information is coded at a certain frequency, the control beam could change the way the waveguide directs the information and can then act as an optical switch. This could be amplitude gated or other variations.

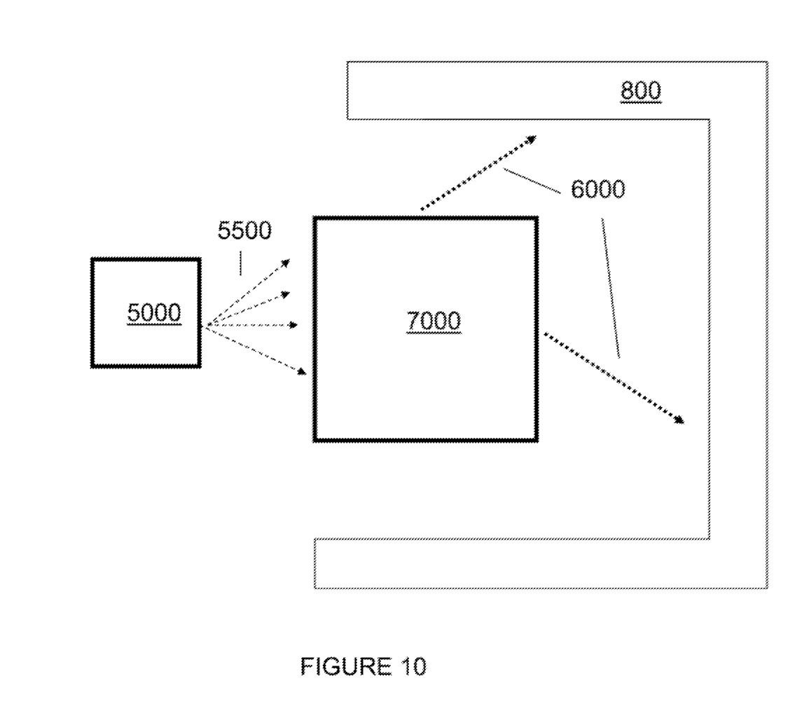

As illustrated in FIG. 10, a laser source 5000 provides a single laser which can be deflected (directed) in multiple directions, as illustrated by the dashed line arrow 5500. The laser 5500 is inputted into a bicontinuous optical switching structure 7000, at a predetermined point of entry or angle.

Within the bicontinuous optical switching structure 7000, active electronic circuits, such as laser diodes may be embedded on the hyperbolic surface of the bicontinuous structure such that when the laser 5500 hits the embedded laser diode, the laser diode is activated. Thus, the single laser 5500 can produce output signals 6000.

The exiting lasers 6000 can be collected by a device 800 for sensing, further transmission, processing, and/or modulation, etc.

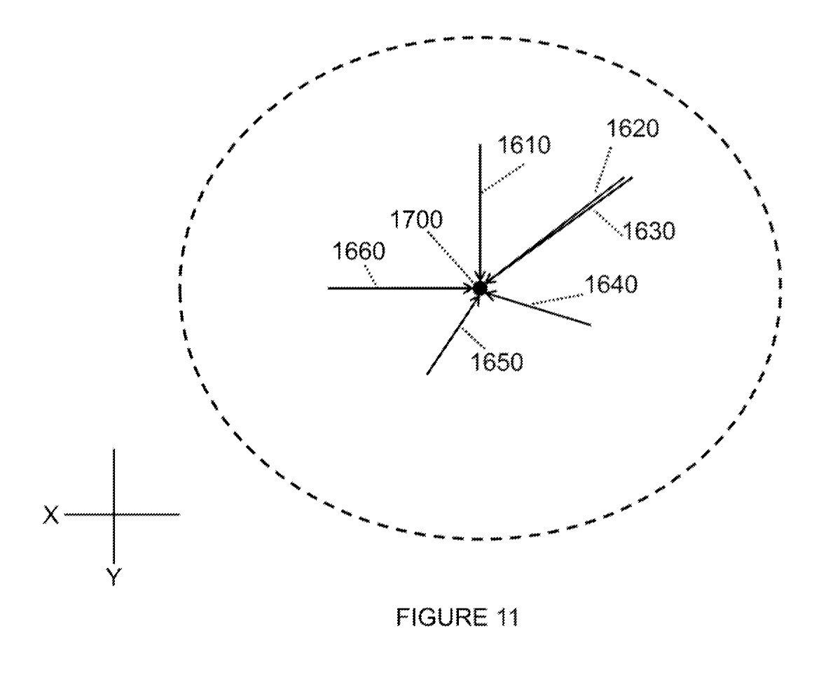

FIG. 11 illustrates possible angles of entry for a laser beam (1610, 1620, 1630, 1640, and 1650) at an entry point 1700. As illustrated in FIG. 11, the Figure shows the X-Y plane looking down upon the face of a tunnel opening in a bicontinuous structure.

It is noted that, in this example, potential laser beams 1620 and 1630 follow the same X-Y projection but start from different elevation in the Z direction. In other words, the starting point for laser beam 1620 is (X,Y,Z₁) XYZ space, whereas the starting point for laser beam 1630 is (X,Y,Z₂) in XYZ space.

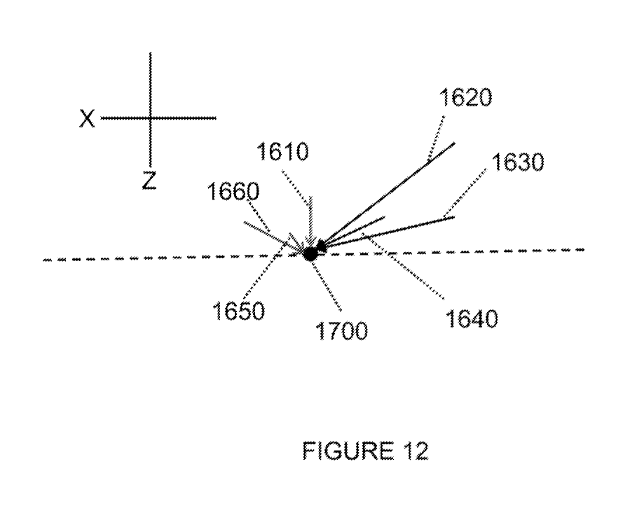

FIG. 12 illustrates possible angles of entry for a laser beam (1610, 1620, 1630, 1640, and 1650) at an entry point 1700. As illustrated in FIG. 12, the Figure shows the X-Z plane across the face of a tunnel opening in a bicontinuous structure.

It is noted that, in this example, potential laser beams 1620 and 1630 lie in the same X-Y plane but start from different points in the Z direction.

It is noted that the hyperbolic bicontinuous structures within the switching device may be coated electro-optic coatings; such as Bragg mirrors that contain periodically spaced layers of non-linear optical materials; that change reflective properties in response to certain light characteristics.

It is further noted that the electro-optic coatings may be elements that interact with photons, such as a lens, diffraction grating, prisms, mirrors, lasers, photodiode, photovoltaic cell, etc.

It is also noted that the light may be photons in the visible spectrum, UV light, or infrared light, x-ray or any other light in the electromagnetic spectrum.

As noted above, the predictability of entry and exit beam pairs is dependent on the pathway through the hyperbolic bicontinuous structures.

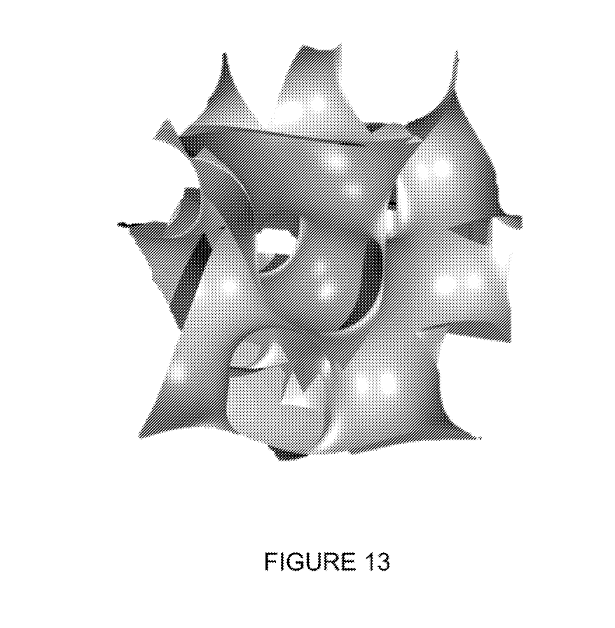

FIG. 13 illustrates an example of a device having multiple hyperbolic bicontinuous structures forming mutually interpenetrating labyrinths.

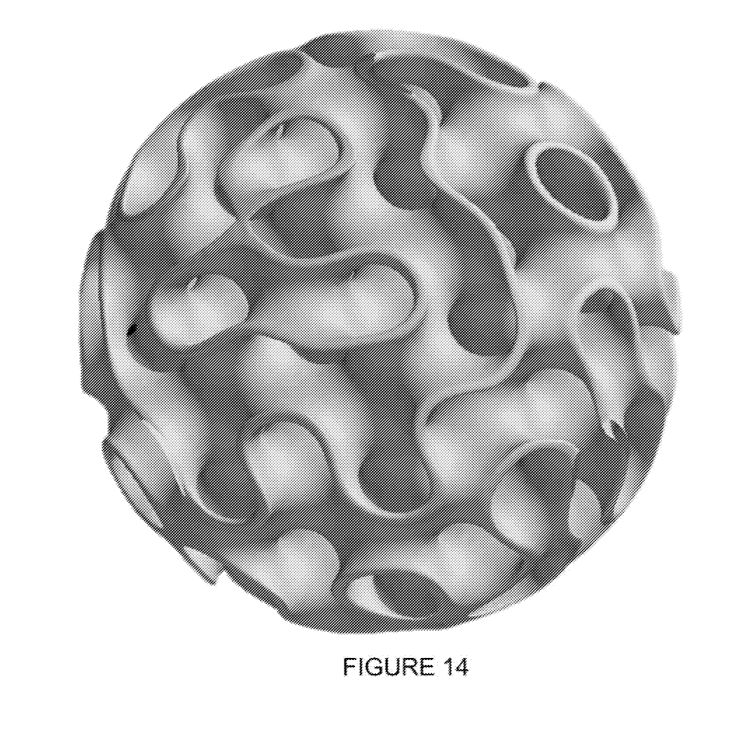

FIG. 14 illustrates another example of a device having multiple hyperbolic bicontinuous structures forming mutually interpenetrating labyrinths.

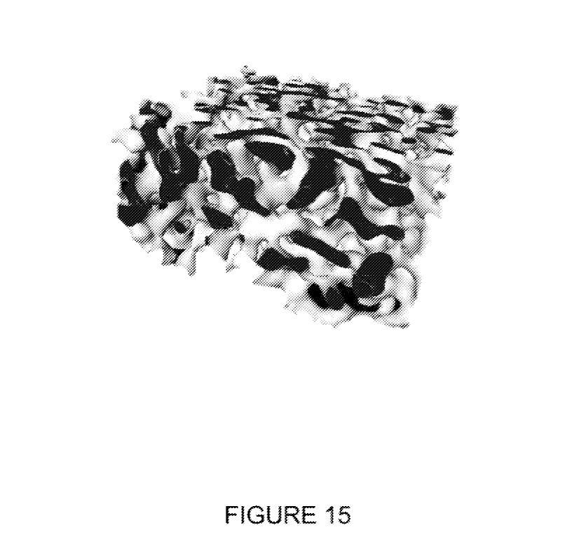

FIG. 15 illustrates a third example of a device having multiple hyperbolic bicontinuous structures forming mutually interpenetrating labyrinths.

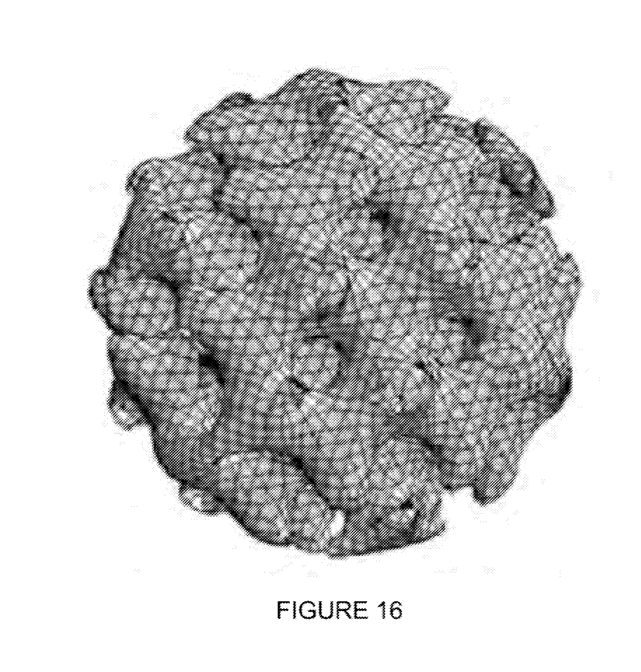

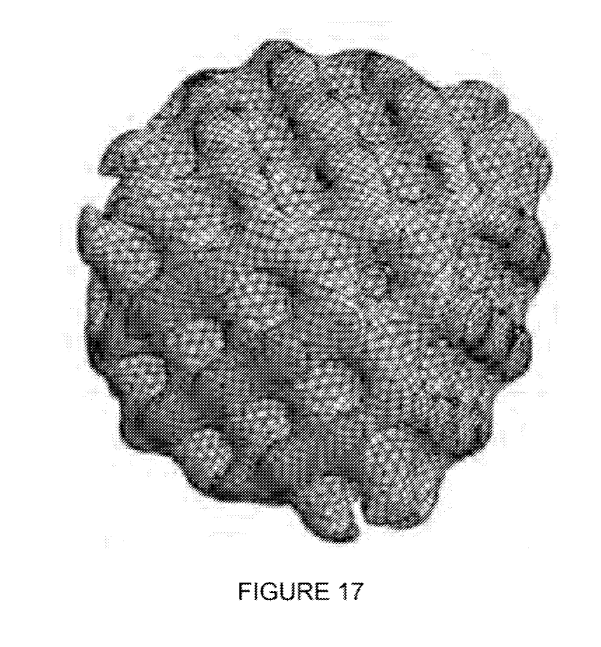

It is noted that the bicontinuous or polycontinuous structures and variations thereof may have one set of tunnels closed in order to eliminate any edges. Examples of such structures are illustrated in FIGS. 16 and 17.

FIG. 16 illustrates a D-surface cubosome closed by a sphere.

FIG. 17 illustrates a D-surface cubosome closed by a cube.

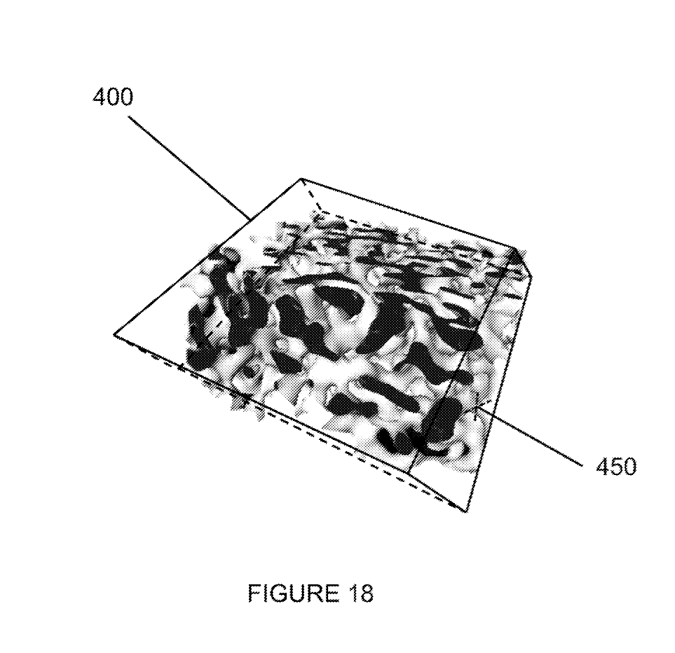

FIG. 18 illustrates an annotated example of a device having multiple hyperbolic bicontinuous structures forming mutually interpenetrating labyrinths. As illustrated in FIG. 16, the device forms a virtual volume 400 with surfaces 450. In this example, the device forms a cubic or rectangular volume; however, various polygonal volumes could be realized.

In FIG. 18, the device includes hyperbolic surfaces which make up the bicontinuous structures. Based upon the characteristics of these critical points, a beam can be aimed close to, but not quite exactly on the critical point, to effect very quick switching, thereby increasing the range of possible paths through the hyperbolic bicontinuous structures. This allows the optical switch to effectively operate at the edge of chaos.

It is noted that the opening and exit of the tunnels to the outside of the structure can be flared out, or otherwise distorted or arranged to enable more or less funneling of light in or out. These flare structures can be separate from the tunnel system to enable funneling of the light into the structure to which the flare structures are seamlessly fused to the tunnel system.

It is further noted that the hyperbolic bicontinuous structures described above may be utilized in various other applications.

For example, the saddle shaped surfaces of the hyperbolic bicontinuous structures may be used in creating a three-dimensional electronic chip or system.

A three-dimensional electronic chip or system allows for better circuitry integration and essentially saves space by going vertical.

The hyperbolic surfaces of the bicontinuous structures described above allow a vertical dimension without losing the existing two-dimensionality of conventional chips or systems. This reduces the physical dimensionality to two without compromising the circuitry.

For example, transistors and other circuitry components can be placed on the disclosed hyperbolic surface, which are connected by wires in the surface or light beams jumping from one part of the surface to another, to create a three-dimensional hyperbolic chip or system.

In the described and illustrated hyperbolic bicontinuous structures, on the surfaces, any point on the surface can be reached by any other point on the surface. This allows the circuit to have a fully three-dimensional structure, while only requiring a two-dimensional wiring architecture.

It is noted that two-dimensional wiring indicates that the wiring does not leave the surface of the hyperbolic bicontinuous structure. In conventional three dimensional circuit structures, the wiring must travel through the substrate structure to connect to circuits at a different level.

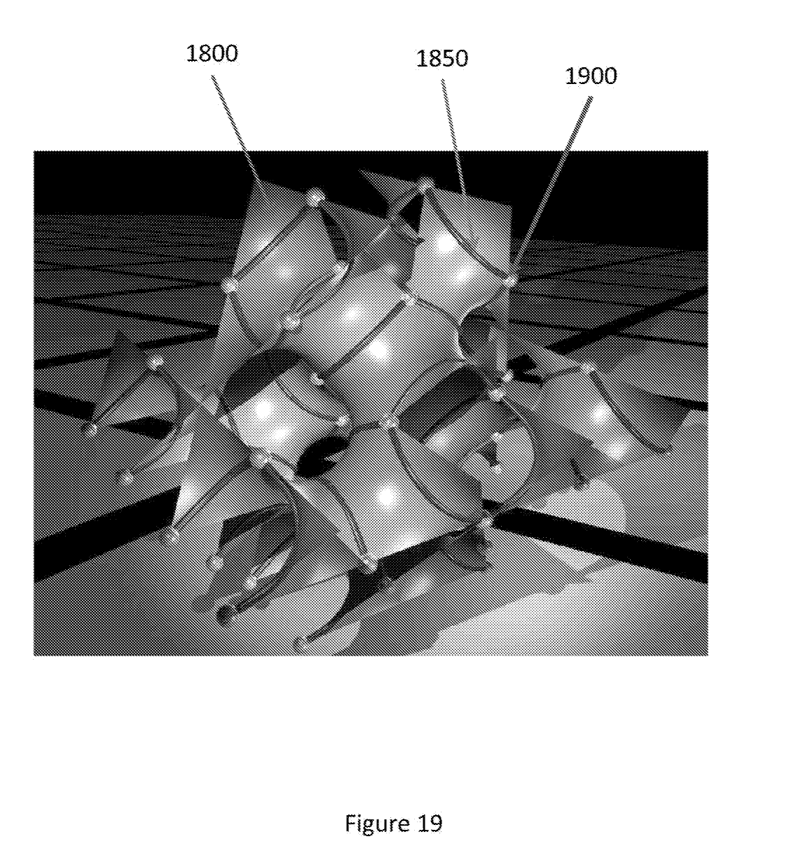

Examples of circuit having a fully three-dimensional structure, while only requiring a two-dimensional wiring architecture, are Illustrated in FIGS. 19-24.

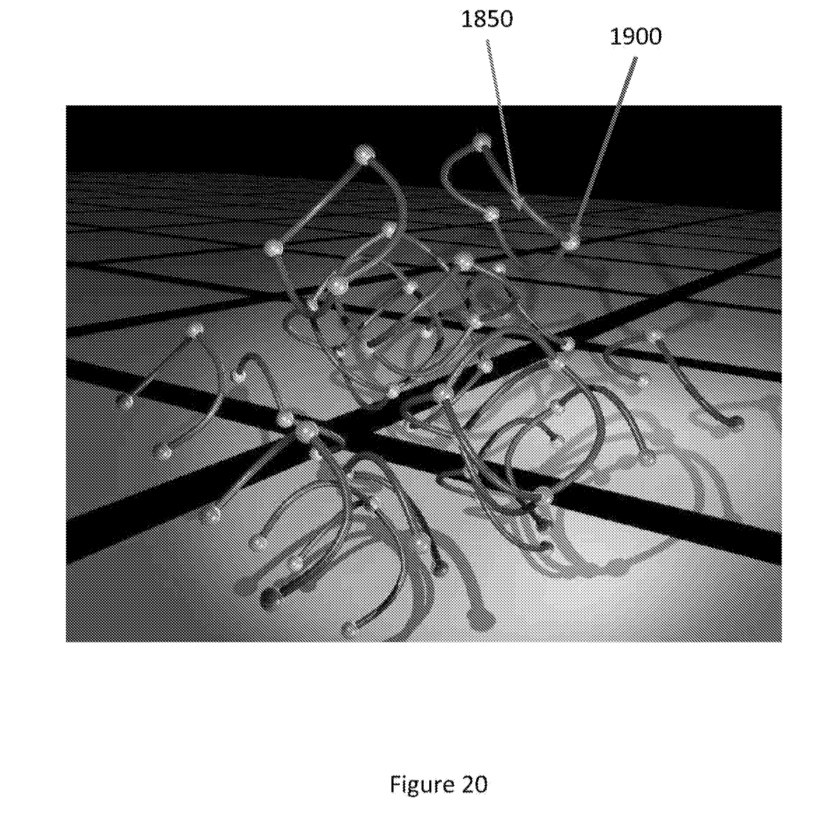

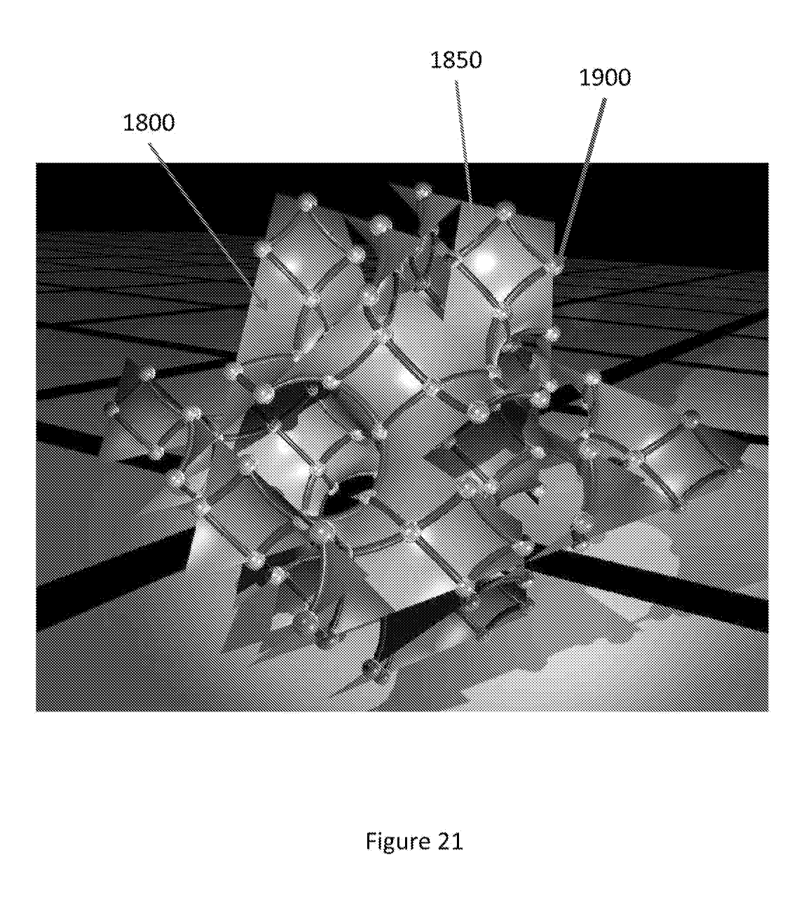

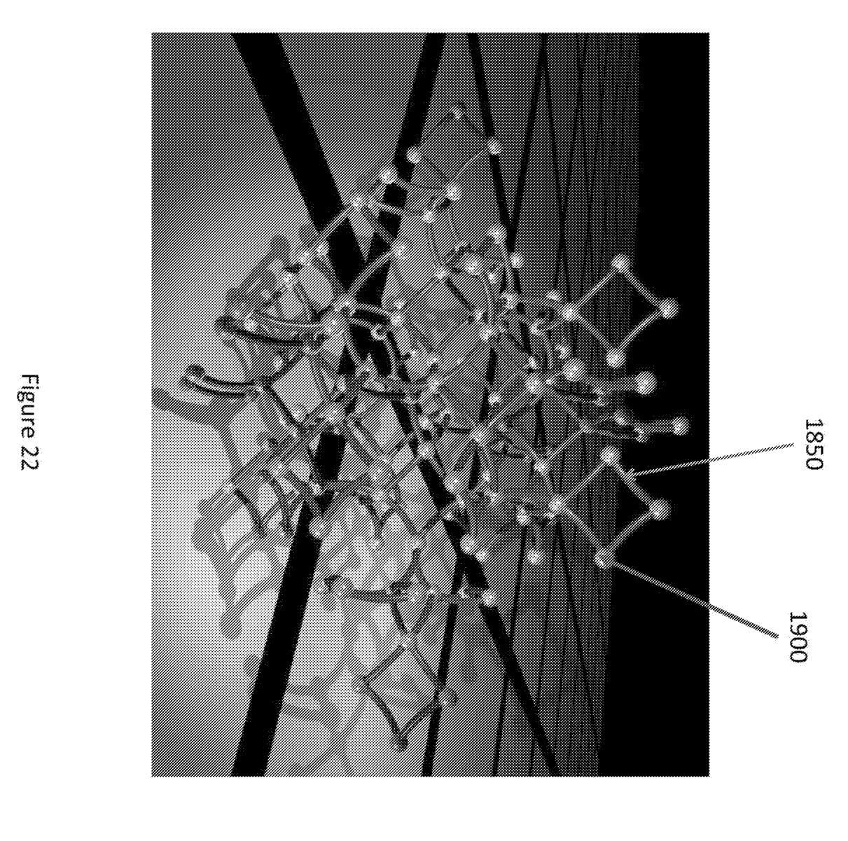

In FIGS. 19 and 21, the Figures show the wiring and circuits with respect to the actual hyperbolic structure. In FIGS. 20 and 22, the Figures show the wiring and circuits without the underlying hyperbolic structure.

As illustrated in FIG. 19, a hyperbolic bicontinuous structure having hyperbolic surfaces 1800 has formed thereon wiring or traces 1850 and circuits 1900. The wiring or traces 1850 are two-dimensional in that the wiring or traces 1850 lie on the hyperbolic surface 1800, but the wiring or traces 1850 can effectively travel three-dimensionally between circuits 1900. This is realized by the curvature of the hyperbolic bicontinuous surface 1800.

FIG. 21 illustrates another example, wherein a hyperbolic bicontinuous structure having hyperbolic surfaces 1800 has formed thereon wiring or traces 1850 and circuits 1900. The wiring or traces 1850 are two-dimensional in that the wiring or traces 1850 lie on the hyperbolic surface 1800, but the wiring or traces 1850 can effectively travel three-dimensionally between circuits 1900. This is realized by the curvature of the hyperbolic bicontinuous surface 1800.

FIG. 20 illustrates the circuit architecture without the hyperbolic bicontinuous surface. As illustrated in FIG. 20, although the wiring or traces 1850 are two-dimensional with respect to the surface, the wiring or traces 1850 can effectively be three-dimensional between circuits 1900.

FIG. 22 illustrates another example, wherein the circuit architecture is shown without the hyperbolic bicontinuous surface. As illustrated in FIG. 22, although the wiring or traces 1850 are two-dimensional with respect to the surface, the wiring or traces 1850 can effectively be three-dimensional between circuits 1900.

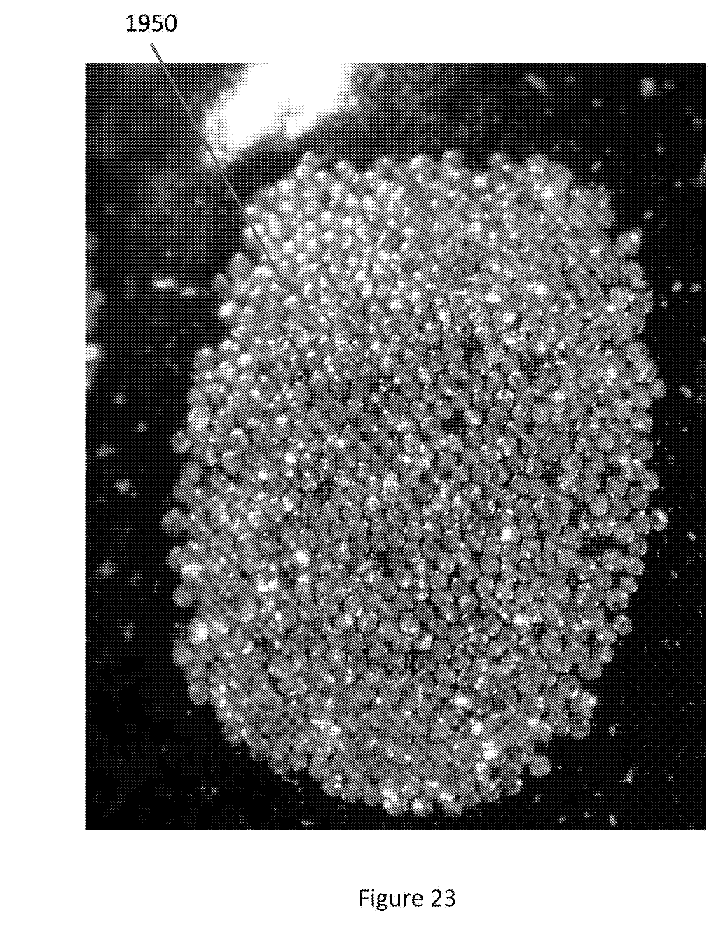

FIG. 23 shows an example of quantum dots or photonic dots.

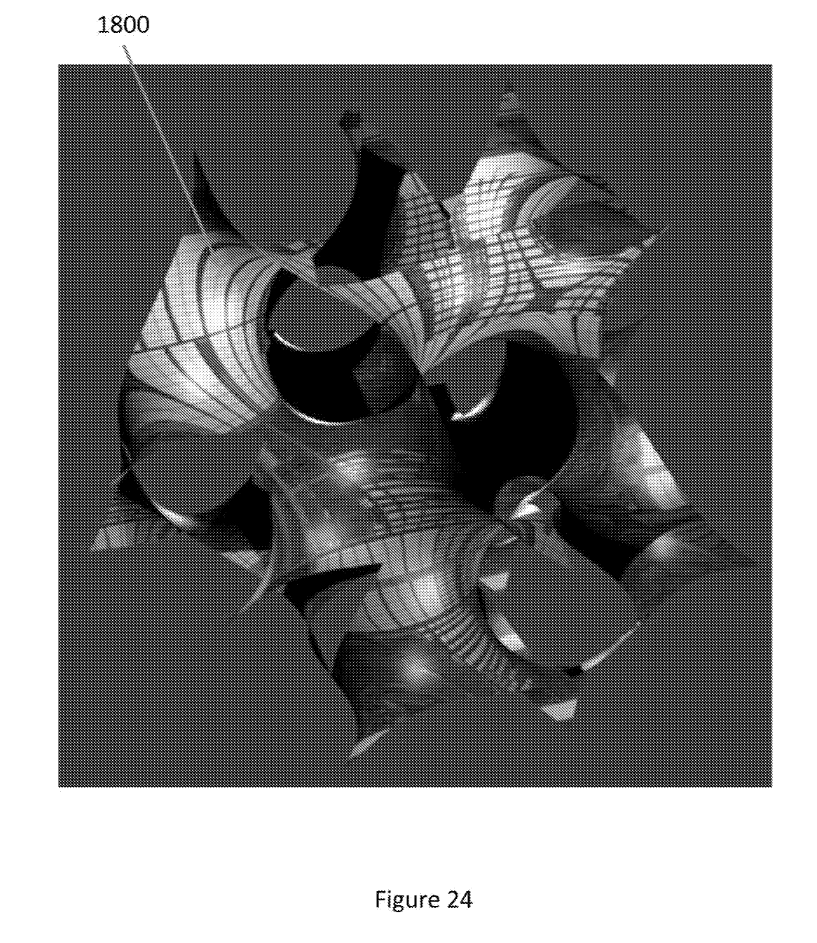

FIG. 24 illustrates an example of a hyperbolic bicontinuous structure.

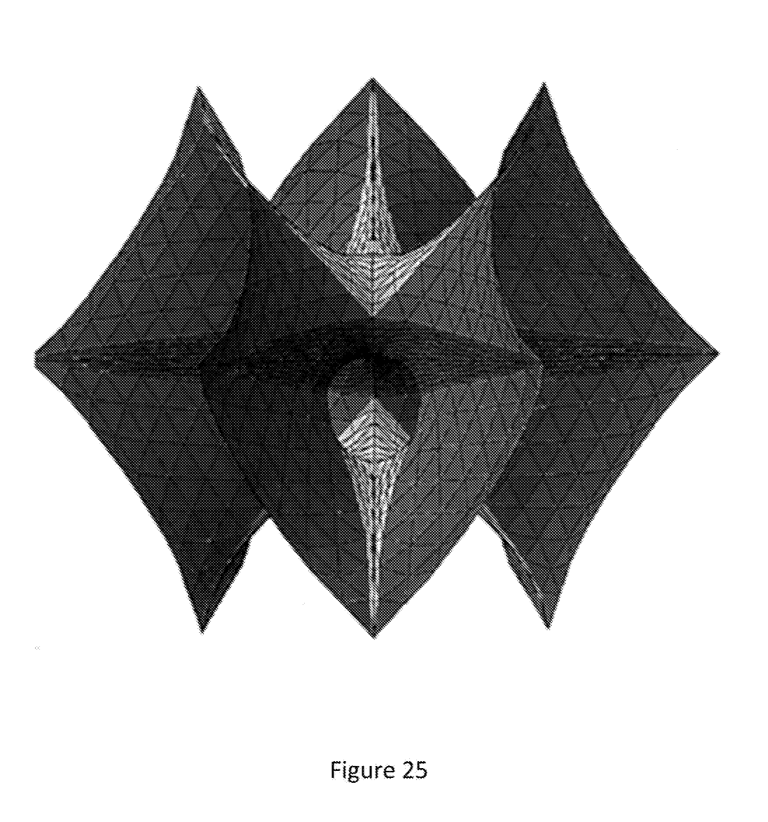

FIG. 25 illustrates an example of a “Batwing’ minimal surface structure.

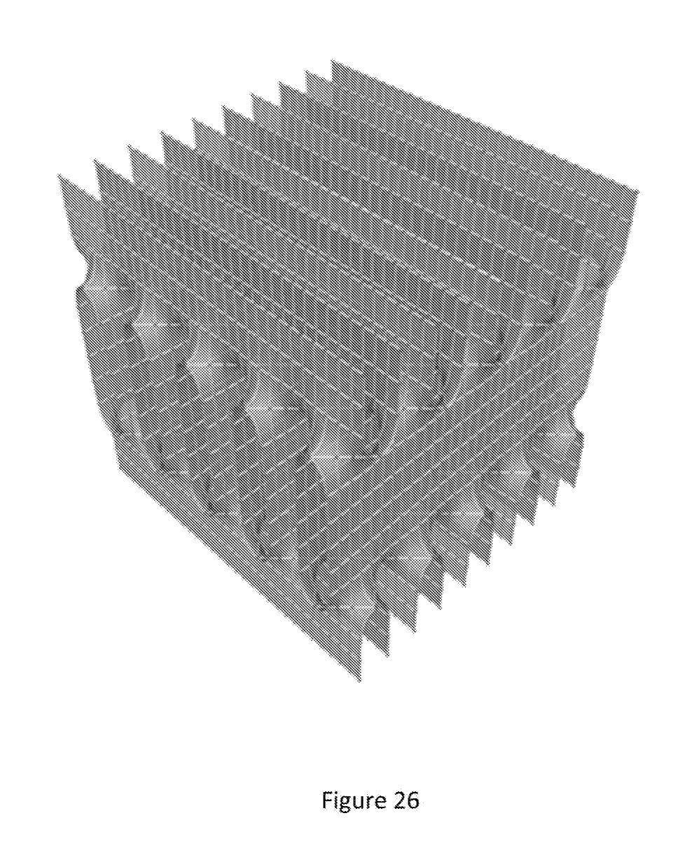

FIG. 26 illustrates an example of a CLP minimal surface structure.

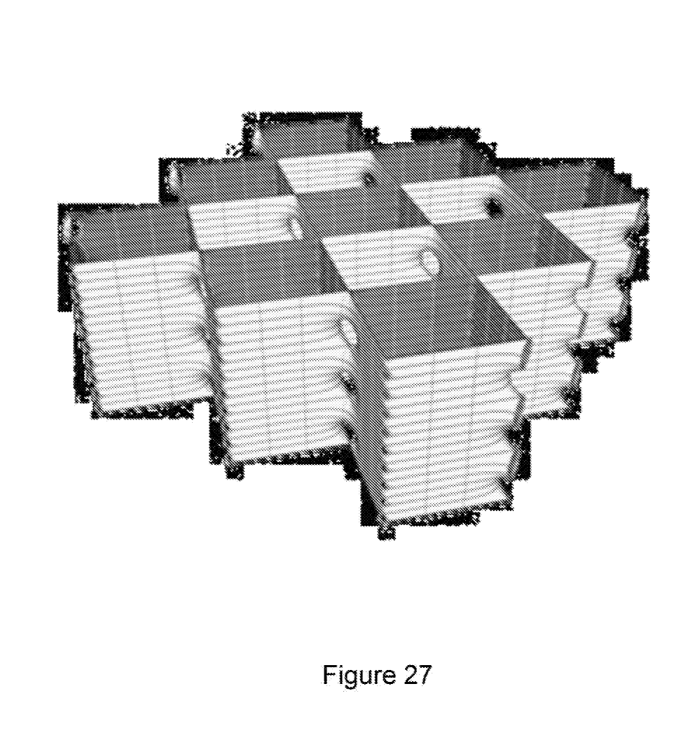

FIG. 27 illustrates another example of a CLP minimal surface structure.

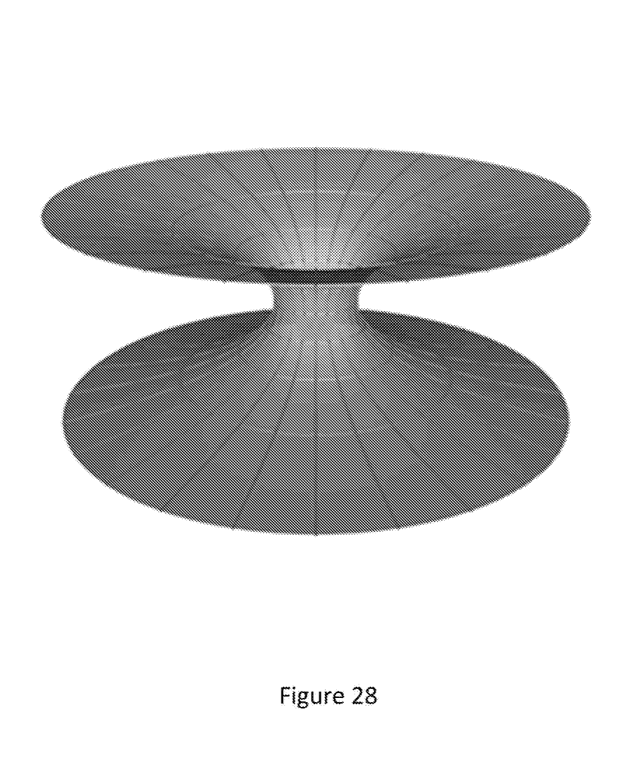

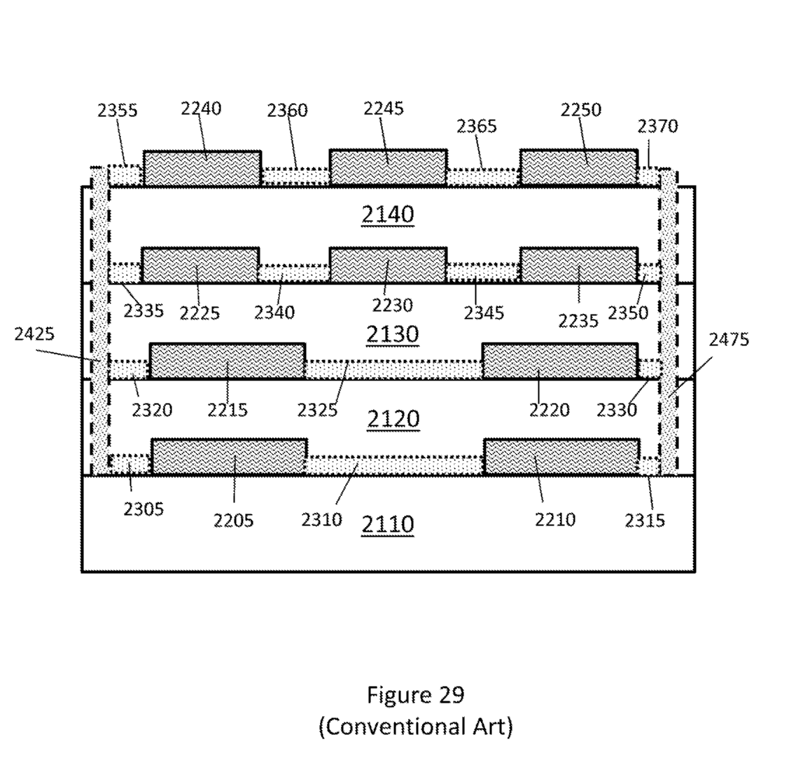

FIG. 28 illustrates an example of a catenoid minimal surface structure.

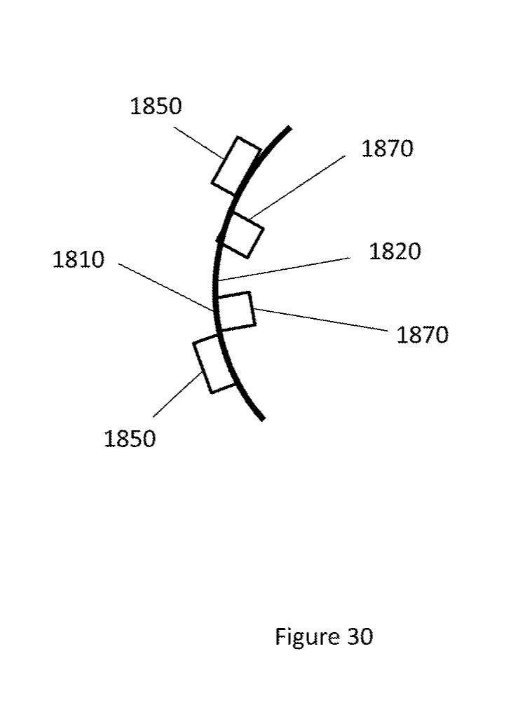

FIG. 30 illustrates an example of locating circuitry on a hyperbolic bicontinuous structure. As illustrated in the example of FIG. 30, a hyperbolic bicontinuous structure has two hyperbolic surfaces 1810 and 1820. These surfaces are two sides of the same structure.

On hyperbolic surface 1810, circuits 1850 are formed, and on hyperbolic surface 1820, circuits 1870 are formed. For most instances, circuits 1850 are electrically isolated from circuits 1870. However, the circuits could be connected with traces that go through the hyperbolic bicontinuous structure; however, such a situation may form tight bends in the connectivity paths.

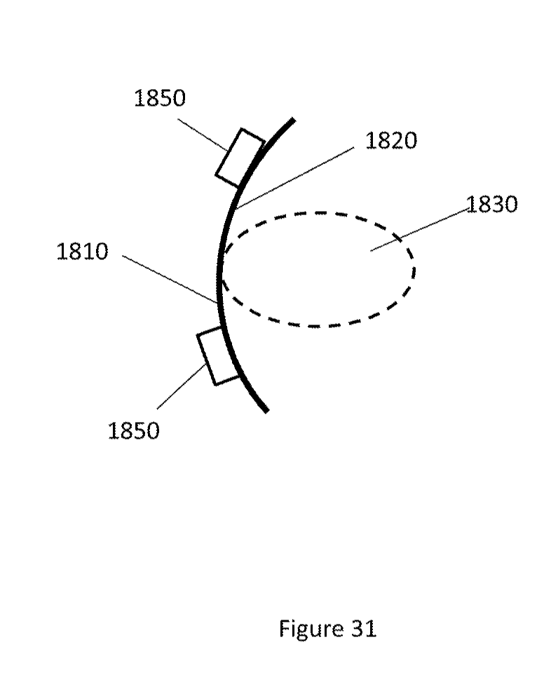

FIG. 31 illustrates an example of locating circuitry on one side of a hyperbolic bicontinuous structure and having a coolant flow along the other side of the hyperbolic bicontinuous structure.

As illustrated in the example of FIG. 31, a hyperbolic bicontinuous structure has two hyperbolic surfaces 1810 and 1820. These surfaces are two sides of the same structure.

On hyperbolic surface 1810, circuits 1850 are formed; however, on hyperbolic surface 1820, no circuits are formed. For this instance, the volume (channel or tunnel) formed by hyperbolic surface 1820 is used for cooling purposes. For example, a coolant fluid could pass through the volume effectively cooling circuits 1850 formed on hyperbolic surface 1810.

It is noted that hyperbolic surface 1820 may also include waveguides for light.

Two-dimensional hyperbolic surfaces also enable higher information and switching density than is possible on a two-dimensional flat chip.

Furthermore, circuits built on the hyperbolic bicontinuous structures may be massively parallel, since the number of unconnected circuits that can be built on the hyperbolic bicontinuous structures is infinite in theory. With respect to flat chips, the number of parallel or otherwise unconnected circuits is limited, by the physical width of the “wires” between logic gates, etc.

It is further noted that conventional “hyperbolic” network topologies have been implemented in packet hopping communications; however, these “hyperbolic” network topologies are achieved virtually by means of wiring up the networks in a certain way that is topologically equivalent to multi-dimensional hyperbolic surfaces.

On the other hand, the hyperbolic bicontinuous structures described above can be utilized to physically place the network nodes (logic gates, etc.) on a hyperbolic surface rather than on a flat surface. The hyperbolic bicontinuous structures physically differ from current chip designs in allowing both physical and virtual hyperbolic networks in the chips or system of chips.

In summary, a three-dimensional chip can be constructed on the hyperbolic bicontinuous structures.

FIG. 23 shows an example of quantum dots or photonic dots. The quantum dots are essentially bicontinuous cubic phases. In this example, the crystals sit in different orientations, and form faceted faces like in a jewel. The use of these quantum dots or photonic dots in a photonic circuit is enabled by manipulating crystal face junctions to achieve certain effects necessary for optical switching. A simple change in the direction of light is simply equated to growing two different facets of the bicontinuous crystal together.

A photonic dot is defined as a photonic crystal that is reduced in size to the point where surface modes of the crystal interact with the light to give non-linear effects. The use of a photonic dot in optical switches enables the design of bistable and tristable optical circuits. The non-linearity of the light interacting with the photonic dots allows an all optical switch because light can change the effective refractive index when incident on an array of photonic dots.

It is noted that a second light path could then be influenced by the first due to a switch in the photonic surface resonance. Dyes and other surface molecules or other matter could help in the control of the non-linear optical circuitry. Based upon this design, AND, NAND OR and NOR gates can be constructed using photonic dots.

In other words, utilization of the photonic dot circuits on the described hyperbolic surfaces a photonic dot circuit based optical computer can be constructed.

Furthermore, since the hyperbolic bicontinuous structures described above have near constant curvature, homogeneous distribution networks can be easily constructed in contrast to the conventional three-dimensional Cartesian grids.

The hyperbolic bicontinuous structures described above also provide a physical geometry for neural net architecture, thereby enabling interfacing live cultured neurons with the hyperbolic surfaces.

Predictability and tunability are intrinsic in the photonic dots on the hyperbolic bicontinuous structures because of the symmetries in these photonic devices. Thus, dielectric mirrors and aspherical dielectric Fresnel lenses and other photonic dots can be combined on the surface enabling various circuits.

These mirrors can be a priori designed to lay on fully predictable networked or fully parallel network topologies. Any one surface of the hyperbolic bicontinuous structure may have a very large number of fully interpenetrating, yet separate graphs or tree networks, producing highly symmetric optical network configurations in various classes of tilings and networks.

The tilings can be seen as the choices of hardware building tiles and the networks as the circuit elements drawn on the tiles. The nodes are sites where photonic devices can sit and direct the flow of optical information by changing state using other optical circuitry.

In these optical circuits, the number of network topology choices is high because of the vast number of possible networks between nodes on the surfaces. Switching just a few dozen nodes in the possible networks on these surfaces gives high density information entropy for fully utilizing the speed of optical circuits.

An example of a simple photonic switch is to use fast photochromics and modulated pulsed lasers. In this example, the header pulse may be long or short (to turn the transmission ON or OFF) and then the subsequent higher frequency pulses are allowed to pass the photochromic film or not. This circuit allows fast optical reactions, color change, beam interference, and optical computing.

It is further noted that the hyperbolic bicontinuous structures may be utilized in optical environments, electrical environments, electro-optical environments, and/or topological insulators.

The hyperbolic bicontinuous structures provide a two-dimensional design with the properties to host three-dimensional networks, have a relative lack of edges on the surfaces, a huge surface area that can be fit into a small volume, and/or enable a large intrinsic information density flow rate.

It is also noted that, as an alternative, the hyperbolic bicontinuous structures may include one side of the surface as having a porous solid three-dimension having millions of node structure points arranged on a symmetric lattice interconnected by struts to form a framework or tree, etc.

The hyperbolic bicontinuous structures may include memristors, thereby enabling either digital or analog computing.

Memristors are resistors that remember the amount of current that has passed therethrough. Memristors can be used as switches and are passive devices so memristors do not lose their memory when turned OFF.

Memristors can be constructed on bicontinuous surfaces using self-assembly and/or three-dimensional lithography. For example, memristors can be implementable on a holographically produced gyroid (bicontinuous surface) using self-assembly of DNA, for example, as a template for nanowires.

The memristor works by changing the position of oxygen vacancies in an array of titania cross-bar latches, which forms a transistor that remembers its former logical state.

By constructing a memristor on a bicontinuous surface, the memristor realizes a greater efficiency (˜300%) of construction on a flat surface and can take advantage of the optimal use of the three-dimensional interconnectivity bicontinuous surfaces provide.

It is noted that light sensitive analogs of memristors may be imprinted on the surface of a bicontinuous mirror or on an optical circuit embedded on a bicontinuous surface. This is also applicable to meminductors and memcapacitors.

It is further noted that the above description has been directed to bicontinuous surfaces. The various descriptions are also applicable to multicontinuous surfaces.

It is further noted that the bicontinuous surface structures can support coolant flow on one side of the bicontinuous surface.

In other words, one side of the bicontinuous surface supports the physical circuits, while the other side of the bicontinuous surface provides the channel for allowing the flow of coolant, thereby effectively cooling the circuitry in an isolated manner.

It is noted that the bicontinuous surface structures can be utilized to channel light so as to form a photonic circuit or circuits.

There are two main ways to channel the light, use a magnetic field or use nonlinear optical materials.

The magnetic field changes the polarization of light, the orientation of the light's electric-field lines, so that light going one way does not interfere with light going the other way.

The nonlinear optical material changes the light's frequency rather than its polarization.

Thus, it is noted that the bicontinuous surface structures can include grooves or waveguides of nonlinear optical material or magnetic field generating circuitry to channel light along the surfaces.

In another application of the bicontinuous surface structure, octagonal chips be implemented on the bicontinuous surfaces.

More specifically, the octagonal chips could be bent into the saddles of the bicontinuous surface structure, have their pins and complementary holes on their sides and then connect the chips by a click method to build up the bicontinuous structures.

It is noted that there are a number of geometric variations, for example three-sided, 6-sided, and 7-sided chips.

The distinction between a hyperbolic 8-sided chip and a flat 8-sided chip is explained by dividing the “stop sign” 8-sided chip into 8 triangles that meet in the center. Each central angle is 45°.

Since there are 8 triangles, this adds up to 360°, which is what is expected if a circle is drawn with its center at the center of the chip. In hyperbolic 8-sided chips, the angle is always greater than 360°, because there is more room. This provides the extra surface area compared with flat chips.

Anticlastic surface is another name for a hyperbolic surface. However it is defined as hyperbolic everywhere but the edges. The bicontinuous surfaces are made by continuously assembling anticlastic or hyperbolic patches to form tunnels. They also differ by having flat points of zero curvature.

Anticlastic surfaces are used commercially for the tension roofs at airports, sports stadiums (parks), and entertainment venues and as architectural focus pieces.

Using anticlastic architectural surfaces, electronic circuits can be built on the hyperbolic patches and then the small portions can be assembled into bicontinuous surfaces.

It is noted that bicontinuous refers to the local condition where the surface separates two labyrinthine sets of tunnels. However, it is not valid at the edges of the structure, since the surface terminates and can therefore not separate anything.

It is further noted that for three-dimensional chips, it is not necessary to have a completely hyperbolic surface, as it may, in some cases, be sufficient to have a set of two-dimensional stacked chips joined by a surface that is locally hyperbolic. However, it is noted that a bicontinuous surface maximizes speed except for the local flat points, not just flat surfaces joined by tunnels.

It is noted that a flexible anticlastic fabric may be made of a flexible solar films with embedded circuitry for architectural purposes, and a solar concentrator may be made from a reflective bicontinuous surface that funnels and concentrates light downwards into the structure for further use.

In summary, minimal surfaces are local hyperbolic patches, and these local hyperbolic patches can be built into global shapes such as bicontinuous surfaces. Examples of the periodic bicontinuous minimal surfaces are the G, the D, and the P surfaces.

A point on a surface, in two dimensions, has two principal curvatures that define its surface curvature. The two surface curvature statistics are the mean (H) and the Gaussian (K) curvatures. There are two types of mean curvature, wherein the H curvature is special when it is zero because the surface is balanced; i.e., the integral of the curvatures on one side equals the other. Otherwise, the mean curvature can be constant or not.

Constant mean curvature surfaces include spheres and planes. There are three types of Gaussian curvatures, the product of the two principal curvatures.

The first type of a Gaussian curvature is when the principal curvatures are in the same direction (i.e., the principal curvatures multiply to give positive products−K>0). These types of curvatures are typically closed spheres and distorted closed spheres.

The second type of a Gaussian curvature is when the principal curvatures multiply to give zero (K=0, the surface is flat or a tube).

The third type of a Gaussian curvature is when the principal curvatures of the surface are in opposite directions (K<0). This third type of a Gaussian curvature is a hyperbolic.

When K<0 and H=0, a local hyperbolic curvature is defined as having a minimal surface, and thus, the shortest pathways (geodesics). These are ideal communication pathways as the pathways are short.

On a sphere, a geodesic looks like the curved longitude “lines” or flight paths. On a hyperbolic surface patch, geodesics are short paths and can be surface loops, tunnel loops, and/or spirals in various directions and can form intersecting or non-intersecting networks with well-defined symmetrically arranged nodes with a myriad of controllable connectivity maps and patterns.

The above described hyperbolic bicontinuous structures provide a high degree of predictability about a myriad of different high symmetry circuits that form short path circuit templates that connect in three-dimensional space, but are addressable by only two surface coordinates (i.e. u, v) rather than the normal Euclidean space (x, y and z).

It is also noted that different resonance modes of the circuitry can be used for computing.

For example, a circuit can be constructed by wiring up sets of nodes on the hyperbolic bicontinuous surface in a manner useful for storage, computation, or switching. Components or sub circuitry can be located at nodes so that a complete circuit or device can be made on a single bicontinuous surface. The circuits can have node separations that take advantage of the scale of the curvature. With internode distances much smaller than the curvature of the hyperbolic bicontinuous surface, the circuitry becomes almost flat locally, and normal circuits can be printed. These relatively flat patch sub-circuits, however, can be interconnected at a length scale that is of the same order of the curvature, and therefore these circuits are relatively curved and the circuit becomes three-dimensional when extended along the surface by repeating the pattern, or partially repeating the pattern.

So the scale of circuitry or sub-circuitry to the scale of the curvature needs to be considered when designing the circuitry; however, curvature variations on the surface are not critical for small patches where the internode distance is smaller. The curvature variations should be minimized for maximum performance, particularly when the length scales are similar. The most homogeneous surface is the G-surface. Therefore, circuits built on the G-surface will be the optimal for information transfer density and speed.

It is also noted that the bicontinuous surface can be chiral (optically active), thereby enabling the construction of chiral bar codes by changing pitch from left to right handed. Left and right-handed chiral photonic dots can be read as bright and dark marks.

So, if the chiral photonic dots are in a row, a binary chiral coding can be easily manufactured and printed and detected by modified bar code readers. This may be used in anti-counterfeiting and security inks.

Lastly, various antenna constructions can be organized to conform to various optimization needs. The hyperbolic bicontinuous surfaces may have the surfaces create the needed “loops” to make the needed shape, surface, width, etc. for the desired antenna.

More specifically, an optical signal with a predetermined frequency can be transmitted through a series of bicontinuous balls and order a pathway to form an antenna, even within a solid state framework such as a cell phone case, or the walls of a truck or spacecraft, etc., configured for the type of frequency, signal, distance, etc., of the incoming signal. The optical signal may contain information to cause changes in the surface reflectivity and/or the shape formation or both of the material being used to control the antenna.

In constructing a three-dimensional circuit on a bicontinuous surface structure, graphene ribbons can be utilized.

Graphene ribbons can be cut from larger graphene sheets, or carbon nanotubes can be slit open lengthwise and unfurled. The graphene ribbons provide a band gap—an energy range that cannot be occupied by electrons and that determines the physical properties, such as the switching capability. The width (and edge shape) of the graphene ribbon determines the size of the band gap, thereby influencing the properties of components constructed from the ribbon.

As previously noted, an optical switch includes a plurality of bicontinuous structures, each bicontinuous structure having multiple potential optical entry points and each potential optical entry point having a corresponding optical exit point. Each bicontinuous structure may be coated with an electro-optic coating having reflective properties that change in response to certain light characteristics. Each bicontinuous structure may be hyperbolic. The bicontinuous structures may form mutually interpenetrating labyrinths and contain a hyperbolically curved interface.

Furthermore, an optical switch may include a plurality of tunnels having a surface, each surface having predetermined reflective properties, the tunnels forming mutually interpenetrating labyrinths, each tunnel having multiple potential optical entry points and each potential optical entry point having a corresponding optical exit point. Each tunnel may be coated with an electro-optic coating having reflective properties that change in response to certain light characteristics. Each tunnel may be hyperbolic. The tunnels may be bicontinuous structures forming mutually interpenetrating labyrinths and containing a hyperbolically curved interface.

In addition, an optical switching system includes a laser light source; an optical switch for receiving a laser light beam from said laser light source, said optical switch including a plurality of bicontinuous structures, each bicontinuous structure having multiple potential optical entry points and each potential optical entry point having a corresponding optical exit point; and a light collection device for receiving a laser light beam exiting said optical switch. The laser light source may include a light deflection system for physically changing a direction of the laser light beam such that an angle of incident of the laser light beam upon the optical switch is changed, thereby changing the optical entry point of the laser light beam.

Each bicontinuous structure may be coated with an electro-optic coating having reflective properties that change in response to certain light characteristics. Each bicontinuous structure may be hyperbolic. The bicontinuous structures may form mutually interpenetrating labyrinths and contain a hyperbolically curved interface. The laser light source may generate multiple laser light beams. Each laser light beam may have a distinct optical entry point with respect to said optical switch and/or a distinct optical exit point with respect to said optical switch.

A three-dimensional optical switch includes a plurality of bicontinuous structures. The plurality of bicontinuous structures forms a virtual volume. Each bicontinuous structure has an opening. The openings are located around a virtual surface of the virtual volume. Each opening has multiple potential optical entry points. Each potential optical entry point has a corresponding optical exit point. Each bicontinuous structure may be coated with an electro-optic coating having reflective properties that change in response to certain light characteristics. Each bicontinuous structure may be hyperbolic. The bicontinuous structures may form mutually interpenetrating labyrinths and contain a hyperbolically curved interface. Each opening may include potential optical entry points and potential optical exit points.

Furthermore, the bicontinuous surface structures can be embedded with pigments to create various colors or designs. These bicontinuous surface structures can be further embedded into fabrics.

The bicontinuous surface circuit containing structures can be embedded into plastics to provide antenna or computing power for electronic devices

Moreover, minimal and bicontinuous surfaces where there are no tight bends along any path (or optical waveguides embedded therein) can speed up a signal from point to point, and processing segments can be clustered for optimization along the continuum. In such situations, the curving, flowing surfaces can rise up multiple stories (circuit levels or planes) high and never encounter a 90 degree turn.

For example, in the same vertical height as a ten-layer stack, minimal and bicontinuous surface structures can have three times more transistors and never encounter a 90 degree turn between them. This enables the realization of less heat, less power consumption, optimally shorter paths, and higher connectivity options. The minimal and bicontinuous surface architecture is scalable from connecting logic gates to circuit boards to networked devices.

While various examples and embodiments have been shown and described, it will be appreciated by those skilled in the art that the spirit and scope of the embodiments are not limited to the specific description and drawings herein.

1. An optical switch comprising a plurality of bicontinuous structures, each bicontinuous structure having multiple potential optical entry points and each potential optical entry point having a corresponding optical exit point.

2. The optical switch as claimed in claim 1, wherein each bicontinuous structure is coated with an electro-optic coating.

3. The optical switch as claimed in claim 1, wherein each bicontinuous structure is coated with an electro-optic coating having reflective properties that change in response to certain light characteristics.

4. The optical switch as claimed in claim 1, wherein each bicontinuous structure is hyperbolic.

5. The optical switch as claimed in claim 1, wherein said bicontinuous structures form mutually interpenetrating labyrinths and contain a hyperbolically curved interface.

6. The optical switch as claimed in claim 1, wherein each potential optical entry point is a physical location on said bicontinuous structure.

7. The optical switch as claimed in claim 1, wherein each potential optical entry point corresponds to a different angle of incidence at a physical location on said bicontinuous structure.

8. The optical switch as claimed in claim 1, wherein each potential optical entry point is a physical location on said bicontinuous structure and wherein each potential optical entry point corresponds to a different angle of incidence at a physical location on said bicontinuous structure such that the multiple potential optical entry points form a three-dimensional set of potential optical entry points.

9. An optical switch comprising a plurality of tunnels having a surface, each surface having predetermined reflective properties, the tunnels forming mutually interpenetrating labyrinths, each tunnel representing a set of entry points, each set of entry points having a multitude of entry angles.

10. The optical switch as claimed in claim 9, wherein each tunnel is coated with an electro-optic coating.

11. The optical switch as claimed in claim 9, wherein each tunnel is coated with an electro-optic coating having reflective properties that change in response to certain light characteristics.

12. The optical switch as claimed in claim 9, wherein each tunnel is hyperbolic.

13. The optical switch as claimed in claim 9, wherein said tunnels are bicontinuous structures forming mutually interpenetrating labyrinths and containing a hyperbolically curved interface.

14. An optical switching system comprising:
a laser light source;
an optical switch for receiving a laser light beam from said laser light source, said optical switch including a plurality of bicontinuous structures, each bicontinuous structure having multiple potential optical entry points and each potential optical entry point having a corresponding optical exit point; and
a light collection device for receiving a laser light beam exiting said optical switch.

15. The optical switching system as claimed in claim 14, wherein said laser light source includes a light deflection system for physically changing a direction of the laser light beam such that an angle of incident of the laser light beam upon the optical switch is changed, thereby changing the optical entry point of the laser light beam.

16. The optical switching system as claimed in claim 14, wherein each bicontinuous structure is coated with an electro-optic coating.

17. The optical switching system as claimed in claim 14, wherein each bicontinuous structure is coated with an electro-optic coating having reflective properties that change in response to certain light characteristics.

18. The optical switching system as claimed in claim 14, wherein each bicontinuous structure is hyperbolic.

19. The optical switching system as claimed in claim 14, wherein said bicontinuous structures form mutually interpenetrating labyrinths and contain a hyperbolically curved interface.

20. The optical switching system as claimed in claim 14, wherein said laser light source generates multiple laser light beams, each laser light beam having a distinct optical entry point with respect to said optical switch.

21. The optical switching system as claimed in claim 14, wherein said laser light source generates multiple laser light beams, each laser light beam having a distinct optical exit point with respect to said optical switch.

22. The optical switching system as claimed in claim 14, wherein said laser light source generates multiple laser light beams, each laser light beam having a distinct optical entry point with respect to said optical switch and a distinct optical exit point with respect to said optical switch.

23. A three-dimensional optical switch comprising:
a plurality of bicontinuous structures;
said plurality of bicontinuous structures forming a virtual volume;
each bicontinuous structure having an opening;
said openings being located around a virtual surface of said virtual volume;
each opening having multiple potential optical entry points;
each potential optical entry point having a corresponding optical exit point.

24. The three-dimensional optical switch as claimed in claim 23, wherein each bicontinuous structure is coated with an electro-optic coating.

25. The three-dimensional optical switch as claimed in claim 23, wherein each bicontinuous structure is coated with an electro-optic coating having reflective properties that change in response to certain light characteristics.

26. The three-dimensional optical switch as claimed in claim 23, wherein each bicontinuous structure is hyperbolic.

27. The three-dimensional optical switch as claimed in claim 23, wherein said bicontinuous structures form mutually interpenetrating labyrinths and contain a hyperbolically curved interface.

28. The three-dimensional optical switch as claimed in claim 23, wherein each opening may include potential optical entry points and potential optical exit points.

29. A three-dimensional circuit, comprising:
a hyperbolic bicontinuous structure forming a substrate;
a first set of circuits formed on a first surface of said hyperbolic bicontinuous structure; and
a first set of electrically conductive traces formed between said first set of circuits;
said first set of electrically conductive traces being formed two-dimensionally on said first surface of said hyperbolic bicontinuous structure;
said first set of electrically conductive traces being effectively three-dimensional traces between said first set of circuits.

30. The three-dimensional circuit as claimed in claim 29, wherein a coolant is in contact with a second surface of said hyperbolic bicontinuous structure to provide effective cooling of said first set of circuits.

31. The three-dimensional circuit as claimed in claim 29, further comprising:
a second set of circuits formed on a second surface of said hyperbolic bicontinuous structure; and
a second set of electrically conductive traces formed between said second set of circuits;
said second set of electrically conductive traces being formed two-dimensionally on said second surface of said hyperbolic bicontinuous structure;
said second set of electrically conductive traces being effectively three-dimensional traces between said second set of circuits.

32. The three-dimensional circuit as claimed in claim 29, wherein said hyperbolic bicontinuous structure forms a plurality of tunnels having a surface, the tunnels forming mutually interpenetrating labyrinths.

33. The three-dimensional circuit as claimed in claim 30, wherein said hyperbolic bicontinuous structure forms a plurality of tunnels having a surface, the tunnels forming mutually interpenetrating labyrinths, one of the tunnels providing the conduit for the coolant.
